(19) United States
(12) Patent Application Publication
(10) Pub. No.: US 2025/0291007 A1
(43) Pub. Date: Sep. 18, 2025

(54) MRI Bore Projector System

(71) Applicant: UX Platforms, Inc., La Jolla, CA (US)

(72) Inventors: Matthew Ferris, Encinitas, CA (US); Simon Whalen, San Diego, CA (US)

(21) Appl. No.: 18/602,550

(22) Filed: Mar. 12, 2024

(51) Int. Cl. G01R 33/28; G03B 21/14; G03B 21/16

(52) U.S. Cl. CPC G01R 33/283; G03B 21/145; G03B 21/16

(57) ABSTRACT

Various embodiments of a method and apparatus including a projector for an MRI system are disclosed. The projector is enclosed in a metal housing with a heat exchanger of various embodiments of fins and surface areas to function as a heat sink. In some embodiments, the surface area of the heat sinks is large enough to reliably function within a magnetic field of up to 3 Tesla without overheating. In some embodiments, the projector is cooled by the heat sink without a fan or internal cooling. In an embodiment, the housing of the projector shields the projector and forces electromagnetic radiation to follow a path that includes a 90-degree turn to escape the interior of the projector, reducing the likelihood of electromagnetic radiation escaping.

### CROSS REFERENCE TO RELATED APPLICATIONS

This application incorporates by reference U.S. patent application Ser. No. ______ Docket No. UX-002-PAP, entitled, “MRI PROJECTOR VIEWING SYSTEM” by MATTHEW FERRIS AND SIMON WHALEN.

### BACKGROUND

### Technical Field

The disclosed method and apparatus relate generally to systems for projecting images. In particular, the disclosed method and apparatus relate to a system for projecting images to a patient, while undergoing an MRI (Magnetic Resonance Imaging) scan.

### Background

It is commonplace today to include fans for cooling projectors. However, within the high magnetic fields generated by an MRI (Magnetic Resonance Imaging), inductors, fans and other electrical and electromagnetic equipment tend to not function as intended to sufficiently cool the projector. Additionally, the projectors generate electromagnetic radiation, which can interfere with the MRI process.

Accordingly, it would be advantageous to provide a system that can project an image to a patient receiving an MRI, without interfering with the MRI and without overheating.

### SUMMARY

Various embodiments of a method and apparatus for a system and method for projecting images on an MRI bore of an MRI system are disclosed.

A projector is enclosed in a housing that functions as a heat sink and a Faraday cage. In some embodiments, the housing is made from a conductive material, which in some embodiments is metallic. In some embodiments, the metallic material is aluminum. Fins are attached to the housing to increase the surface area of the heat sink and thereby increase the effectiveness of the heat sink. In some embodiments, the surface area of the heat sink is large enough to passively cool the projector (cooling all electromagnetic components) to reliably function within a magnetic field of up to 3 Tesla without the projector overheating. In some embodiments, the heat sink cools the projector without a fan or other internal cooling.

In some embodiments, a lid for accessing the interior of the projector sits on a ledge (within the interior) that makes a 90-degree angle with the walls of the interior of the projector. Consequently, since the electromagnetic radiation is essentially blocked or severely attenuated by the metallic walls, for electromagnetic radiation to escape from the projector via the separation between the lid and the rest of the housing of the projector, the electromagnetic radiation needs to follow a path that includes at least a 90-degree turn formed by (1) the ledge of the interior, (2) the walls of the interior and (3) the lid, which reduces the likelihood of electromagnetic radiation escaping the interior of the projector housing. Traveling through the 90-degree turns significantly attenuates the electromagnetic radiation—preventing or hindering the radiation from exiting the projector housing.

The projector is placed in a magnet room associated with the MRI system and a server is installed in an equipment room that is electromagnetically isolated from the magnet room. A cable, which in some embodiments is quad-shielded, connects the projector to a server. The server runs a module on the server that controls the projector (a control module), which in some embodiments includes controlling a controller. Running the software on the server instead of the projector reduces the processing power needed by the projector. By reducing the processing power in the projector, the projector can be kept lightweight, and the power consumed by the projector can be reduced. Reducing the power of the projector reduces the amount of heat that the projector generates and the amount of electromagnetic radiation emitted by the projector is reduced.

In some embodiments, the server receives control signals from a client device in a control room. In some embodiments, a UI (User Interface) is resident on the client device that includes an on/off button (or other on/off-link) for turning the projector on and off. In some embodiments, the UI is a GUI (Graphical User Interface). In some embodiments, the server provides router services/IOT (Internet Of Things) services allowing the client device to control the projector, via the server.

In some embodiments, the server also includes a library of content to play. The library stores a group of images, in which there are multiple versions of each of several images. Each version of the same image, when projected by the projector, produces an image that is appropriate for a different MRI system, allowing the same projector system to be used with different types of MRI systems. In some embodiments, each version of the same image, when projected by the projector, produces an image that is a different size, where the sizes of each version of the image are based on the MRI bore sizes of a different MRI system. In some embodiments, the images include videos. In some embodiments, the server includes a PCB (Printed Circuit Board) that relays power from the power supply to the projector.

In some embodiments, the projector is mounted in a stand and the stand includes (1) a pillar, (2) an arm extending from the pillar and (3) a bracket securing the arm to the pillar. The pillar has slots that run along the length of the pillar. Fasteners are attached to a bracket which is used with the pillar. By loosening the fasteners, the arm may be moved up and down to change the height of the projector. In some embodiments, the fasteners are combinations of nuts and screws. which are placed in the slots and the screws that secure the bracket to the pillar by screwing into the nuts, the fasteners are loosened by loosening the screws. In some embodiments, the screws of the specification are push screws. In some embodiments, the screws are replaced with bolts, and the screw holes are replaced with bolt holes. The cable is attached to, and runs along, the pillar and the arm.

In some embodiments, the stand engages a plate (a “floor lock plate,” “positioning plate” or “locking plate”) that is adhered to the floor. The function of the plate is to aid in guiding the projector system into place after the projector has been moved to a different location (e.g., for storage).

### BRIEF DESCRIPTION OF THE DRAWINGS

The disclosed method and apparatus, in accordance with one or more various embodiments, is described with reference to the following figures. The drawings are provided for purposes of illustration only and merely depict examples of some embodiments of the disclosed method and apparatus. These drawings are provided to facilitate the reader's understanding of the disclosed method and apparatus. They should not be considered to limit the breadth, scope, or applicability of the claimed invention. It should be noted that for clarity and ease of illustration these drawings are not necessarily made to scale.

FIG. 1 illustrates some embodiments of an MRI (Magnetic Resonance Imaging) system in which an MRI projector system has been installed.

FIG. 2 illustrates a topside perspective view of some embodiments of a housing of the projector.

FIG. 3 illustrates a top view of some embodiments of the projector with a lid of the projector removed, allowing an interior region of the housing to be viewed.

FIG. 4 illustrates a cross-sectional view of some embodiments of the housing of FIG. 2 cut along a line, A-A, of FIG. 2.

FIG. 5 illustrates some embodiments of a stand for supporting the projector with the projector attached.

FIGS. 6 and 7 illustrate some embodiments of a pillar-bracket assembly of the stand of FIG. 5. FIG. 6 illustrates a top view of the pillar-bracket assembly with the pillar uncapped, and FIG. 7 illustrates an exploded view of the pillar-bracket assembly.

FIG. 8 illustrates an exploded view of some embodiments of the arm-bracket assembly.

FIG. 9 illustrates some embodiments of adjusting the height of the projector.

FIG. 10 illustrates some embodiments of an MRI bore with alignment markings.

FIG. 11 illustrates some embodiments of a clip and the locations of clips on the stand.

FIGS. 12 and 13 illustrate some embodiments of attaching the base of the stand to the pillar of the stand.

FIGS. 14 and 15 illustrate some embodiments of the base of the stand engaged with a plate that keeps the stand from rolling.

FIG. 16 illustrates a block diagram of some embodiments of the MRI system of FIG. 1.

FIGS. 17 and 18 illustrate examples of videos being projected onto the MRI bore of an MRI system.

FIG. 19 illustrates some embodiments of a page of the UI of the client device having an on/off link that turns the projector of FIG. 1 on and off, where the on/off link is in the off state.

FIG. 20 illustrates some embodiments of a page of the UI of the client device having an on/off link that turns the projector of FIG. 1 on and off, where the on/off link is in the on state.

FIG. 21 illustrates some embodiments of a method of turning on the projector of FIG. 1.

FIG. 22 illustrates some embodiments of a method of setting up the MRI system of FIG. 1.

FIG. 23 illustrates some embodiments of a method of using the UI to control the projector of FIG. 1.

The figures are not intended to be exhaustive or to limit the claimed invention to the precise form disclosed. It should be understood that the disclosed method and apparatus can be practiced with modification and alteration, and that the invention should be limited only by the claims and the equivalents thereof.

### DETAILED DESCRIPTION

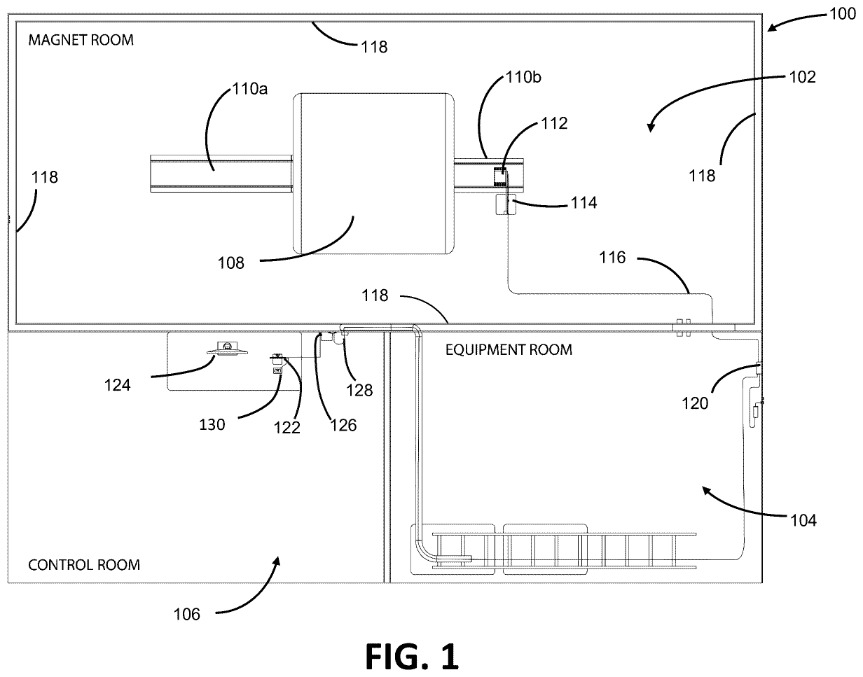

FIG. 1 illustrates some embodiments of an MRI (Magnetic Resonance Imaging) system 100 in which an MRI projector system has been installed. The MRI system includes a magnet room 102, an equipment room 104 and a control room 106.

The MRI is taken in the magnet room 102, which is controlled from the control room 106. The magnet room 102 houses a magnet housing 108, a bed 110a having an extension 110b, a projector 112, a stand 114, a first part of a cable 116 and walls 118. The equipment room 104 houses a second part of the cable 116 and a server 120. The magnet housing 108 houses components of the MRI system 100 that are related to the magnets and the bed 110a. The cable 116 attaches to a penetration panel on the wall 118. The penetration panel filters RF radiation from transmission entering the magnet room 102. In some embodiments, all transmissions from the equipment room 104 to electronic devices in the magnet room 102 pass through the penetration panel. The extension 110b houses pulleys for moving the parts of the bed 110a that move the patient in and out of the magnet housing 108 as well as other equipment. The extension 110b is optional. The pulleys and other equipment housed by the extension 110b can be placed elsewhere, such as in the magnet housing 108.

The projector 112 projects images (which are optical or visible images) onto the walls of the MRI bore of the magnet housing 108. The stand 114 supports the projector 112 while the projector 112 is projecting images. The cable 116 carries communication signals from the server 120 to the projector 112, enabling the server 120 to control the projector 112. Running programs that control the projector 112, on the server 120 instead of in the projector 112, allows the projector 112 to (1) have less processing power, (2) be lighter and (3) generate less electromagnetic radiation and heat. By generating less electromagnetic radiation, the projector 112 is less likely to interfere with the MRI. Since less heat is produced, the projector 112 is less likely to overheat. Also, since the projector 112 can be lighter, the projector/stand assembly can be more stable and less likely to sway or topple. In some embodiments, the cable 116 also carries the power to the projector 112. In some embodiments, the cable 116 is coaxial and quad-shielded so that electromagnetic radiation generated by the cable 116 does not interfere with the MRI. In some embodiments, the client device 122 and the server 120 communicate wirelessly. In some embodiments, an ethernet cable or other communications cable connects the client device 122 to the server 120.

In some embodiments, the walls 118 of the magnet room 102 shield the magnet room 102 from electromagnetic radiation from outside of the magnet room 102 that would otherwise interfere with the MRI. In some embodiments, the equipment room 104 houses equipment related to the MRI system 100.

The control room 106 houses devices that host an interface via which users can control the MRI system 100 and projector 112. In some embodiments, some of the devices in the control room 106 include a client device 122 and a computer 124. In some embodiments, the client device 122 is a tablet computer. A power supply 126 supplies/regulates power for an AP (Access Point) 128 and the client device 122. In some embodiments, the power supply 126 is located in the control room 106 and connects to the server 120 which in some embodiments is in a computer box. The AP 128 acts as a gateway to the server 120. Auxiliary audio switch 130 switches between playing the audio files stored in the server 120 and audio files stored elsewhere or in another network.

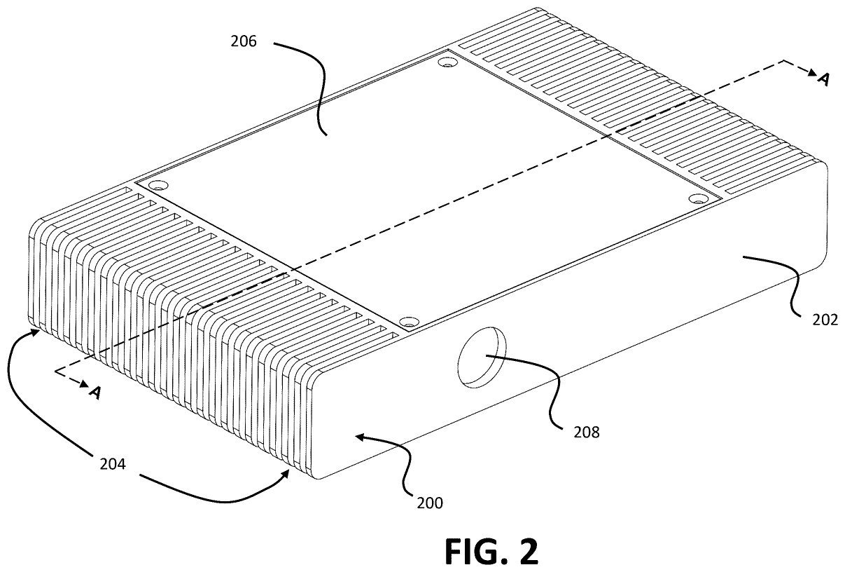

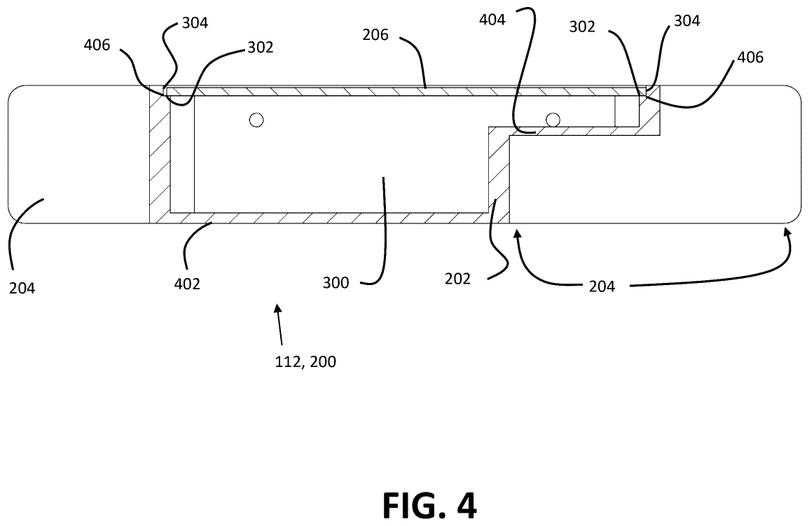

FIG. 2 illustrates a topside of a housing 200 of the projector 112. The housing 200 includes a casing 202, fins 204, a lid 206 and a lens system 208, and FIG. 2 also shows cutline A-A (cutline A-A is discussed in conjunction with FIG. 4). In some embodiments, the casing 202 is made of a metallic or conductive material that is a good heat conductor, so that the casing 202 cools the projector 112 and hinders or prevents electromagnetic radiation from leaking out of the housing 200. The fins 204 increase the surface area of the heat sink formed by the housing 200 (and the fins 204), facilitating the housing 200 (plus the fins 204) to act as a more effective heat sink (than the housing 200 alone). As a result of keeping the surface area of the heat sink (that is, the surface area of the housing 200 plus the surface area of the fins 204) above a predetermined threshold area no internal cooling or fans are necessary. In some embodiments, the fins 204 are formed by extrusion. The lid 206 can be removed to access the electronics and other hardware of the projector 112. In some embodiments, the interior includes threaded posts into which screws are screwed to hold the lid 206 on the housing 200. The lens system 208 projects an image from the projector 112. In some embodiments, components of the lens system 208 are fixed in position reducing the number of servos in the projector 112, which would generate heat.

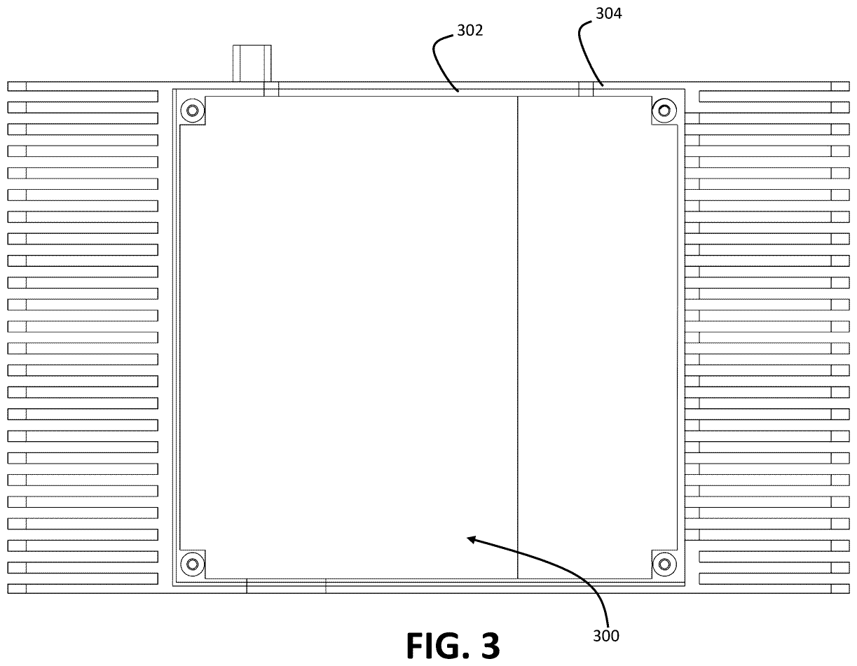

FIG. 3 illustrates an interior region 300 of the housing 200. At an edge of the interior region 300 is a ledge 302, which forms a 90-degree angle with the walls of the housing 200. Placing the lid 206 on the ledge 302 creates the 90-degree turn through which electromagnetic radiation needs to travel to exit the interior region 300. Requiring the electromagnetic radiation to travel through the 90-degree turn, attenuates the electromagnetic radiation, preventing or at least reducing the amount of electromagnetic radiation that leaks from the interior region 300, via separations between the lid 206 and the rest of the housing 200. The 90-degree angle formed by the ledge 302 and a wall 304 is also shown in FIG. 4, which is discussed below.

FIG. 4 illustrates a cross-section of the housing 200 formed by cutting the housing 200 along cut-line A-A (see FIG. 2), and FIG. 4 also illustrates a 90-degree turn 406 (formed by (1) the ledge 302, (2) the wall 304 and (3) the lid 206) the 90-degree turn is also discussed above in conjunction with FIG. 3. In some embodiments, when viewed from the bottom, a portion 402 of the casing 202 is visible having no fins. Another portion 404 of the bottom of the casing 202 is covered with the fins 204, further aiding in cooling the projector 112. In other embodiments, the fins 204 are arranged differently, and cover different portions of the casing 202, so long as the resulting heat sink has a surface area that is greater than a minimum surface area needed for passively cooling the projector without the need for internal cooling. Additionally, the minimum surface area is in part dependent on the material that the fins 204 and the casing 202 are made from.

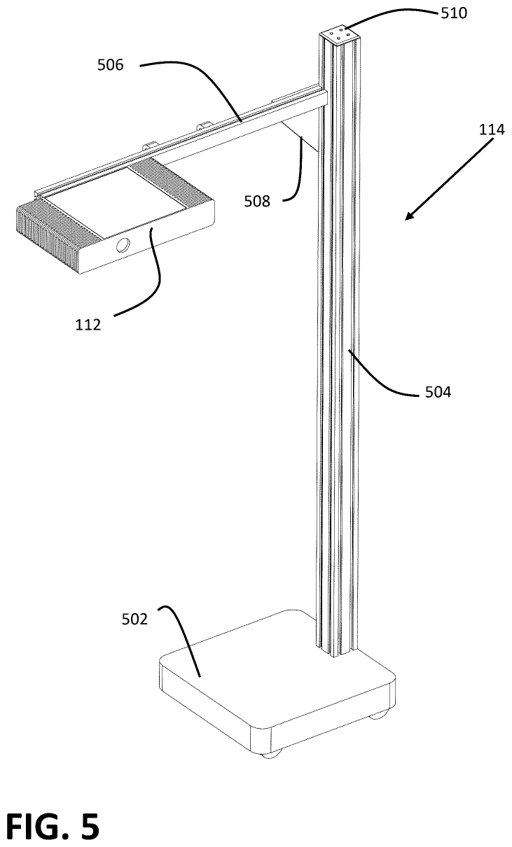

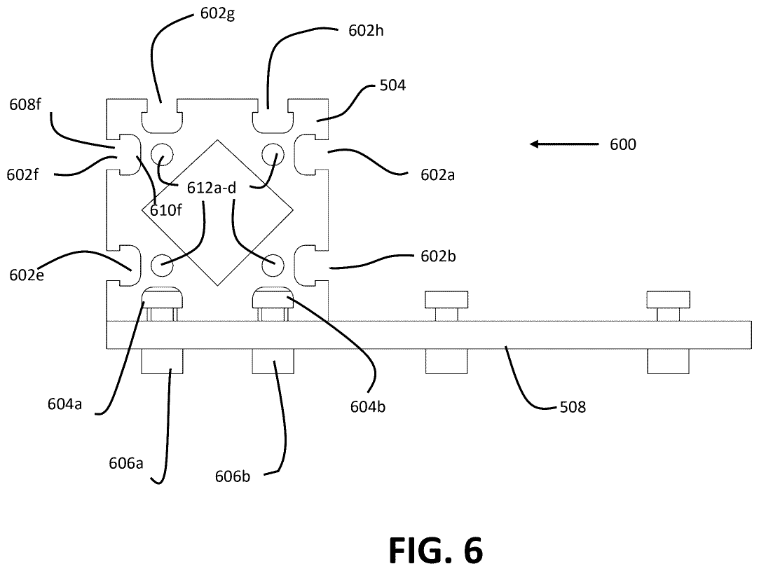

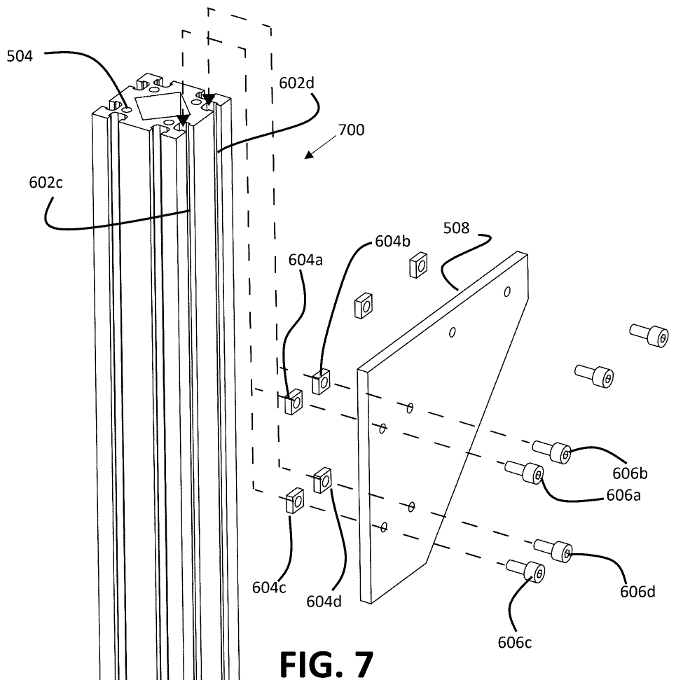

FIG. 5 illustrates some embodiments of the stand 114 for supporting the projector 112. The stand 114 includes a base 502, which supports a pillar 504 (which could also be a post). An arm 506 is adjustably secured to a top portion of the pillar 504. A bracket 508 supports and stabilizes the arm 506 and attaches the arm 506 to the pillar 504. The projector 112 is attached to the arm 506. A cap 510 is attached to a top of the pillar 504 (which is discussed in conjunction with FIG. 7). Adjusting the height of the projector 112 (and the arm 506 and the bracket 508) is discussed below in conjunction with FIGS. 6 and 7. In some embodiments, the base 502, the pillar 504, the arm 506, and optionally other components of the stand 114 are made from nonconductive rigid high-density material. In some embodiments, rigid high-density material is a thermoplastic. In some embodiments, the thermoplastic is a polyethylene monomer. In some embodiment, nonconductive rigid high-density material HDPE (High-Density Polyethylene).

FIGS. 6 and 7 illustrate some embodiments of the pillar-bracket assembly (and the mechanism by which bracket 508 is attached to the pillar 504). FIG. 6 illustrates a top cross-sectional view 600 of the pillar-bracket assembly, while FIG. 7 illustrates a partially exploded view of the pillar-bracket assembly. In some embodiments, each side of the pillar 504 includes at least one slot (in some embodiments, there are two slots on each side of the pillar 504), which in the embodiments of FIGS. 6 and 7 include slots 602a-h. In some embodiments, nuts 604a-d are placed into two of the slots (which in some embodiments includes the slots 602c and d), and in some embodiments, at least two nuts are placed into each of the slots 602c and d), which are located on one of the sides of the pillar 504. Specifically, in the embodiments of FIG. 7, the nuts 604a and c are placed in the slot 602c, and the nuts 604b and d are placed in the slot 602d. The slots 602a-f have openings (e.g., 608f) that are narrower than an interior (e.g., 610f) of the slots 602a-d. Consequently, once the nuts 604a-d are in the slots 602c and d, the nuts 604a-d can slide up and down, along the slots 602c and d, while staying in the slots 602c and d. However, the nuts 604a-d cannot be pulled vertically out of the slots 602c and d, in a direction that is perpendicular to a length of the slots 602c and d, without deforming the slots. In some embodiments, after placing the nuts 604a-d into the slots 602c and d, screws 606a-d are placed through holes in the bracket 508 and then into the nuts 604a-d, thereby securing the bracket 508 to the pillar 504. Alternatively, the nuts 604a-d could be placed into the slots 602c-d after the screws 606a-d are placed through holes in the bracket 508 and then into the nuts 604a-d.

Subsequently, by loosening the screws 606a-d, moving the bracket 508 up or down and then tightening the screws 606a-d, the height of the projector 112 can be adjusted. Alternatively, in some embodiments, the screw holes (instead of the nuts) of the screws 606a-d are placed in the slots and the nuts are loosened and tightened to secure the bracket 508 to the pillar 504. Although in the embodiment of FIG. 7, there are four adjustment-push-screws, in other embodiments there are a different number of adjustment screws (e.g., 4, 6 or 8) (the adjustment screws are screws that are loosened to allow the height of the projector 112 to be adjusted). In some embodiments, the upward movement of the arm 506 and the bracket 508 is blocked or at least hindered by the cap 510, so that the bracket 508 does not inadvertently slide off the pillar 504 while adjusting the height of the projector 112. Holes 612a-d accept screws that hold the cap 510 (FIG. 5) on the pillar 504.

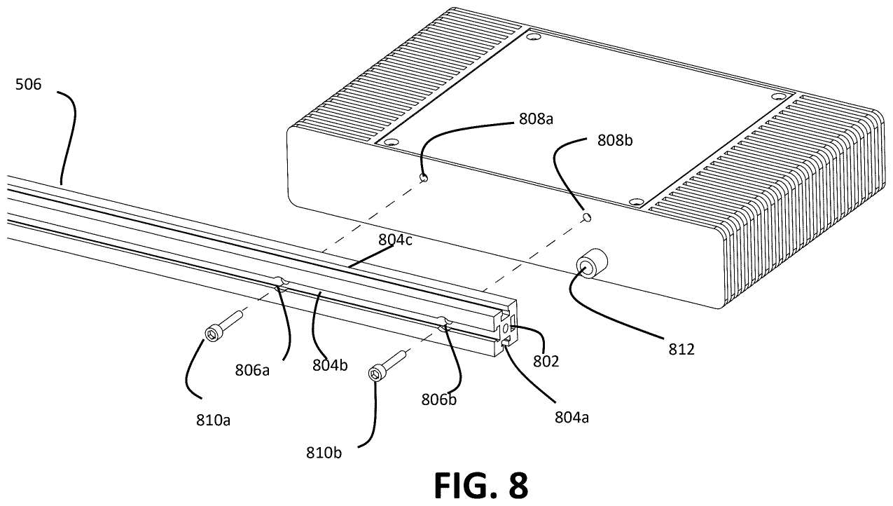

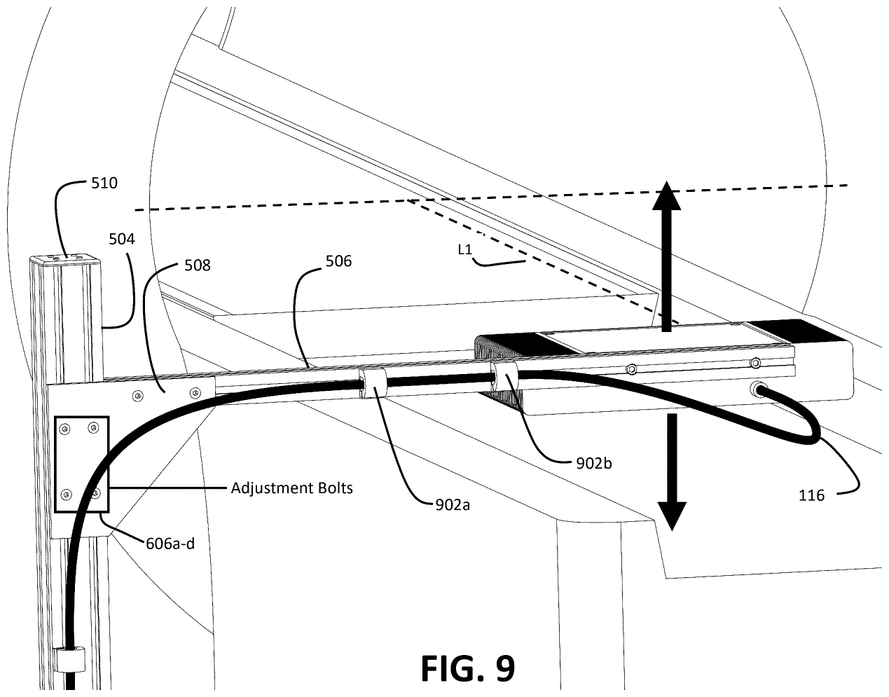

FIG. 8 illustrates a top view of the arm-projector assembly, which illustrates a structure in which the arm 506 is connected to the projector 112. At an end of the arm 506 (which in FIG. 8 is uncapped), a structure of a cross-section 802 of the arm 506 is visible, and slots 804a-c have openings that are narrower than their interiors (similar to the slots of the pillar 504). The slots 804a-c are discussed in conjunction with FIG. 9. The arm 506 has two holes 806a and b and the projector 112 has two holes 808a and b, which align with the two holes 806a and b. Screws 810a and b are received by the holes 806a and b (in the arm 506) and the two holes 808a and b (in the projector 112) to hold the arm 506 and the projector 112 together. In some embodiments, the arm 506 and the pillar 504 are made of a heat conductive material, so that the pillar 504, the arm 506 and the housing 200 when fastened together act as a large heatsink that cools the projector 112. In some embodiments, the heat-conductive material is electrically conductive. In some embodiments, the conductive material is metallic, which in some embodiments is aluminum. In some embodiments, an electrical connector 812—e.g., a BNC (Bayonet Neill-Concelman) connector or coaxial connector-accepts the cable 116 to power and carry control signals to the projector 112.

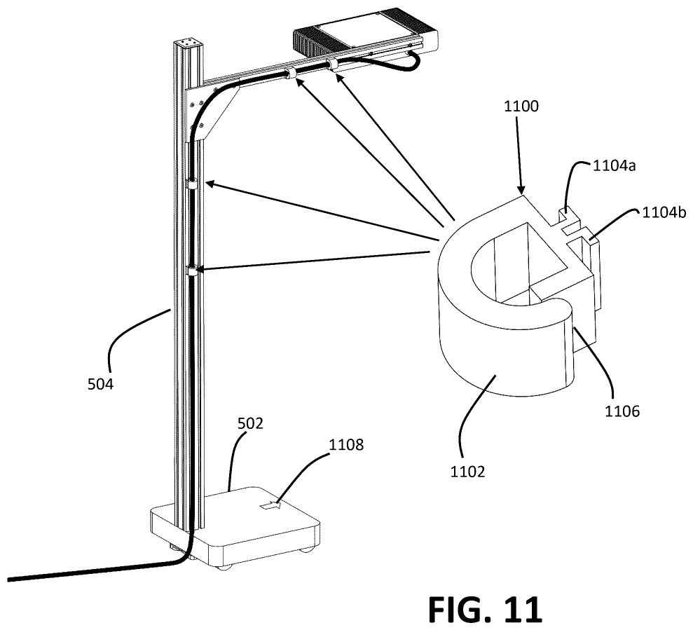

FIG. 9 also illustrates a manner for securing the cable 116 to the stand 114 and illustrates adjusting the height of the projector 112. The cable 116 runs along (1) the arm 506, (2) the bracket 508 and (3) the pillar 504. The cable 116 is attached to the arm 506 by clips 902a and b. The clips 902a and b wrap around the cable 116 and engage the slot 804b (the slots 804b on the arm 506 that the clips 902a and b engage with are shown in FIG. 8 and the clips are further discussed in conjunction with FIG. 11). The slots 804a-c accept clips for holding the cable 116 on the arm 506. The rectangle surrounding the screws 606a-d indicates that the screws 606a-d are used for adjusting the height of the projector 112, as discussed above in conjunction with FIG. 6. The distance L1 (drawn as a dashed line) is the distance at which to place the projector 114 from the MRI bore. The dashed line that is perpendicular to the line representing the distance L1 extends across the exterior of the opening of the bore. In some embodiments, to simplify the instructions, the distance L1 is kept the same no matter the MRI system 100, and then the version of the content that is displayed depends on the dimensions of the bore/MRI system 100.

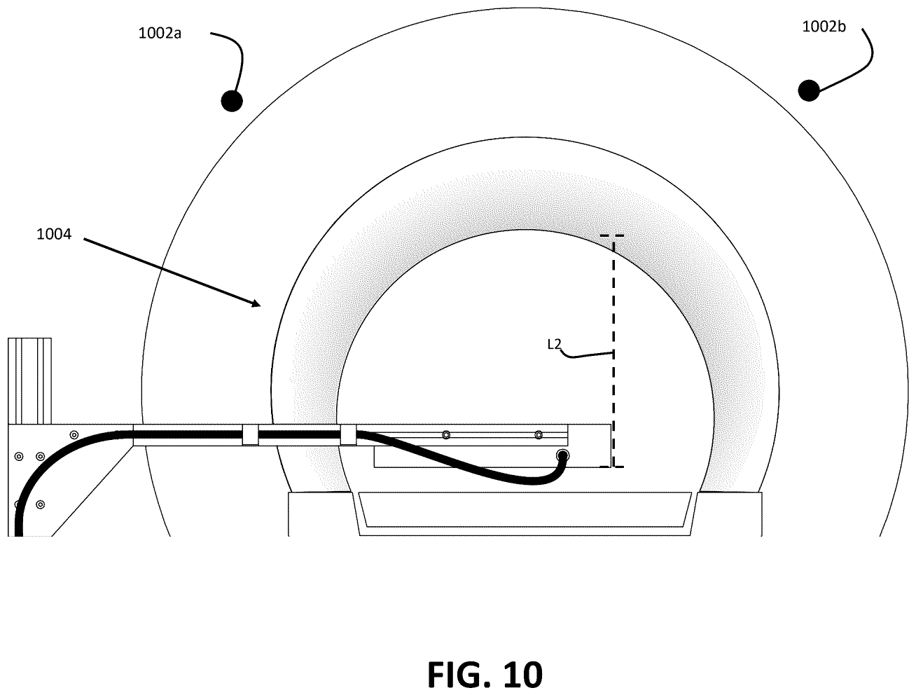

FIG. 10 illustrates the location of alignment markings 1002a and b on the opening of an MRI bore 1004. During alignment, the projector 112 projects images that include images of alignment markings. Initially, the image is aligned without using the alignment markings 1002a and b. The image is initially centered within the MRI bore 1004, with the lens system 208 of the projector 112 centered, horizontally, with respect to the MRI bore 1004. If the projector 112 is placed too far upward or downward or is pointing in the wrong direction, the image will be at least somewhat out of alignment in a similar manner. After alignment, the alignment markings 1002a and b are placed on the opening to the MRI bore 1004, and aligned with, the image of the alignment markings 1002a and b. In some embodiments, the alignment markings 1002a and b are placed at approximately the 10:00 and 2:00 positions. In some embodiments, the alignment markings 1002a and b are green dots.

However, in other embodiments, other shapes and colors are used as the alignment markings 1002a and b, and there could be more alignment markings. However, using more alignment markings or more complicated shapes increases the likelihood of the user misplacing or misorienting one of the alignment markings, which could make the alignment markings less useful. Although there is a chance of the user misplacing one of the two alignment dots 1002a and b, the tolerance is great enough that the misplacement is unlikely to be a problem, and aligning the image with just two alignment dots is doable, even if one is slightly misplaced. By contrast, aligning the image with three alignment dots may not be doable if one is slightly misplaced. Similarly, if two squares or other polygons are used (instead of dots), and one of the squares is rotated slightly, the user may not be able to align the image of the alignment markings with the physical alignment markings. The length L2 indicates the distance from the bottom of the projector 112 to the top of the bore. In some embodiments, the length L2 is adjusted based on the diameter of the bore, to keep the lens of the projector 112 at the center of the diameter of the bore. In some embodiments, a ratio of a distance from the center of the bore to the lens to the diameter of the bore is kept fixed.

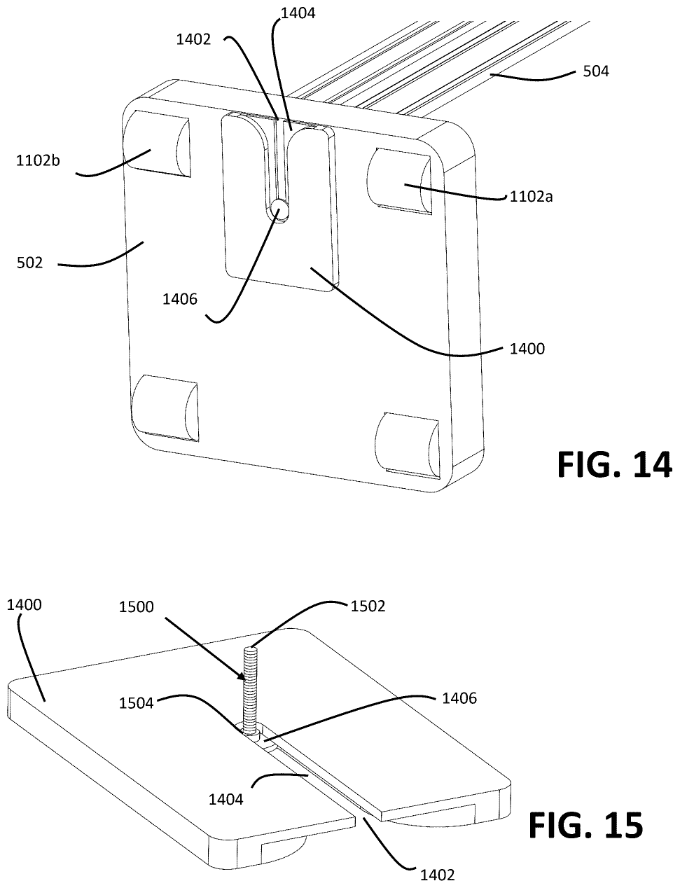

FIG. 11 illustrates an example of a clip 1100, which can be used to secure the cable 116 to the stand 114. The clip 1100 includes a clasp 1102 and feet 1104a and b. The clasp 1102 separates at a mouth 1106, via which the cable 116 can be inserted into the clasp 1102. The feet 1104a and b are sloped pointing away from the clasp 1102 and are separated from one another by a gap. The sloping of the feet 1104a and b eases the feet 1104a and b into the slots 602a-h. The gap allows the feet 1104a and b to flex and be pressed towards one another, while being inserted into the slots 602a-h, which facilitates inserting the clip 1100 into the slots 602a-h. In some embodiments, the structure of the clips 902a and b is the same as the clip 1100. The slot 804b in which the clips 902a and b fit on the arm 508 is shown in FIG. 8 and discussed in conjunction with FIG. 9. FIG. 11 also shows a directional marking 1108, which is discussed in conjunction with FIG. 14.

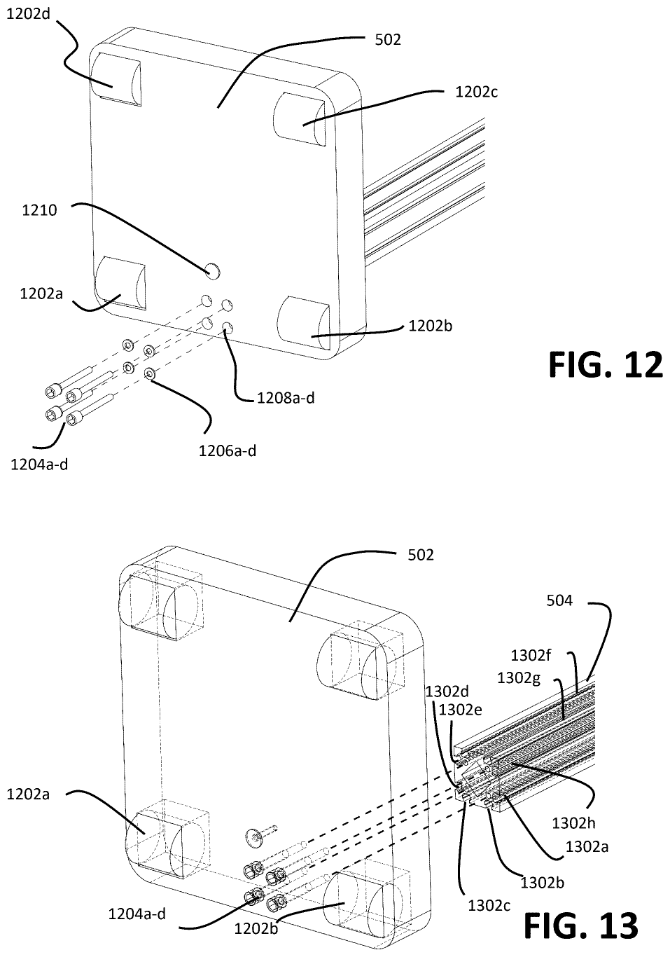

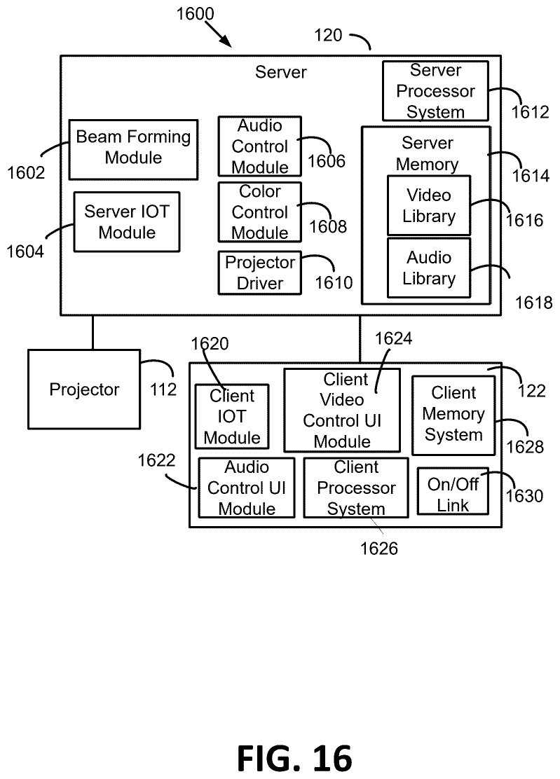

FIGS. 12 and 13 illustrate the bottom of the base 502 and how the base 502 is connected to the pillar 504. In some embodiments, the bottom of the base 502 includes (1) four wheels 1202a-d (or four rollers or our skates) and (2) four screws 1204a-d, which engage four washers 1206a-d, which are placed into four wells 1208a-d, which includes holes within which the four screws 1204a-d extend through. Each of the four wells 1208a-d includes a threaded screw hole. The base 502 includes a well 1210, which includes a screw hole located in the center of the bottom of the base 502, which will be discussed in conjunction with FIGS. 14 and 16. As illustrated in FIG. 13, in some embodiments, the bottom of the pillar 504 has four screw holes 1302a-n, which engage the four screws 1204a-d to hold the pillar 504 to the base 502.

FIG. 14 illustrates an example of a plate 1400 for keeping the stand 114 from rolling (the plate 1400 can be referred to as a “locking plate” or “floor lock plate”-because the plate 1400 facilitates locking the base 502 in place). In FIG. 14, the plate 1400 is attached to the bottom of the base 502. The plate 1400 includes a gap 1402 between two halves of the plate 1400. A recess 1404 is below a portion of the plate 1400 having the gap 1402. In some embodiments, the heads of two of the four screws 1204a and b are visible through the gap 1402. The screw hole 1406 holds the plate 1400 to the base 502 (after the plate 1400 is slid in place). How the plate 1400 is attached to the base 502 is further discussed in conjunction with FIG. 15.

FIG. 15 illustrates the combination of the plate 1400 with a screw 1500 (without the base 502). The screw 1500 includes a threaded stem 1502 and a base 1500 that connects the threaded stem 1502 to the screw hole 1406. The threaded stem 1502 screws into the screw hole associated with the well 1210 (see FIG. 12). The screw 1500 is already attached to the base 502. The screw 1500 slides into the gap 1402 and stops at the end of the channel to make sure the stand 114 is positioned correctly. The screw 1500 also acts as a pivot so if a patient or equipment on the bed hits the projector 112 the stand 114 can swing out of the way while in the plate 1400. In some embodiments, the plate 1400 is adhered to the floor with double-sided tape.

The direction marking 1108 (see FIG. 11) indicates the direction to roll the stand 114 into the plate 1400 and lock it into position. The stand 114 is placed opposite the plate 1400, with the gap 1402 (1) next to, (2) opens towards and (3) opposite the direction marking 1108. Then, the stand 114 is rolled onto (or over) the plate 1400. As the stand 114 is rolled onto (or over) the plate 1400, the screw 1500 slides into the gap 1402.

FIG. 16 illustrates a block diagram 1600 of the MRI system 100. In some embodiments, the server 120 includes a beamforming module 1602, a server IOT (Internet Of Things) module 1604, an audio control 1606, a color control 1608, a projector driver 1610, a server processor system 1612, a server memory system 1614, a video library 1616 and an audio library 1618. The client device 122 includes a client IOT module 1620, an audio control UI module 1622, a video control UI module 1624, a client processor system 1626, a client memory system 1628 and an on/off-link 1630.

In some embodiments, the beamforming module 1602 shapes and focuses the light emitted from the projector 112. In some embodiments, the beamforming module 1602 is not present. The server IOT module 1604 enables the server 120 to be controlled, via a network (e.g., the Internet or other network), by the client device 122. The audio control 1606 controls the audio being played. The color control 1608 controls the color of the image. In some embodiments, the projector driver 1610 controls the projector 112, which in some embodiments includes controlling the color and brightness of the images, and controls turning the projector 112 on and off. The server processor system 1612 runs the software and the modules of the server 120 and controls the beam forming module 1602, the audio control 1606, the color control 1608, the projector driver 1610, the server memory system 1614, the video library 1616 and the audio library 1618. The video library 1616 and the audio library 1618 store the videos and audio tracks played by the projector 112. In some embodiments, for each video stored in the audio library 1618 of the projector 112, there are multiple versions, and each version is tailored for a different MRI system. In some embodiments, each version produces an image that is differently sized based on a different size MRI bore. The combination of the lens system 208, the images of the video library 1616, and the beam forming parameters of the beam forming module 1602 determine the distance at which the image from the projector 112 is in focus on the MRI bore.

In some embodiments, the client IOT module 1620 includes machine instructions that communicate with the server IOT module 1604. The audio control UI module 1622 presents the audio UI on the client device 122. The video control UI module 1624 presents the video UI to the user of the client device 122. In some embodiments, the audio control UI module 1622, the video control UI module 1624 and the on/off-link 1630 are part of a UI module, which runs a graphical UI (GUI) (that includes the audio UI and the video UI). In some embodiments, the client processor system 1626 runs the client IOT module 1620, the audio control UI module 1622, the video control UI module 1624 and the on/off-link 1630. In embodiments in which an ethernet cable or another communications cable connects the client device 122 to the server 120, the server IOT module 1604 and the client IOT module 1620 need not be present. The on/off-link 1630 causes the client device 122 to send a signal to the server system 120, which in turn causes the server 120 to send a control signal that turns on and off the projector 112.

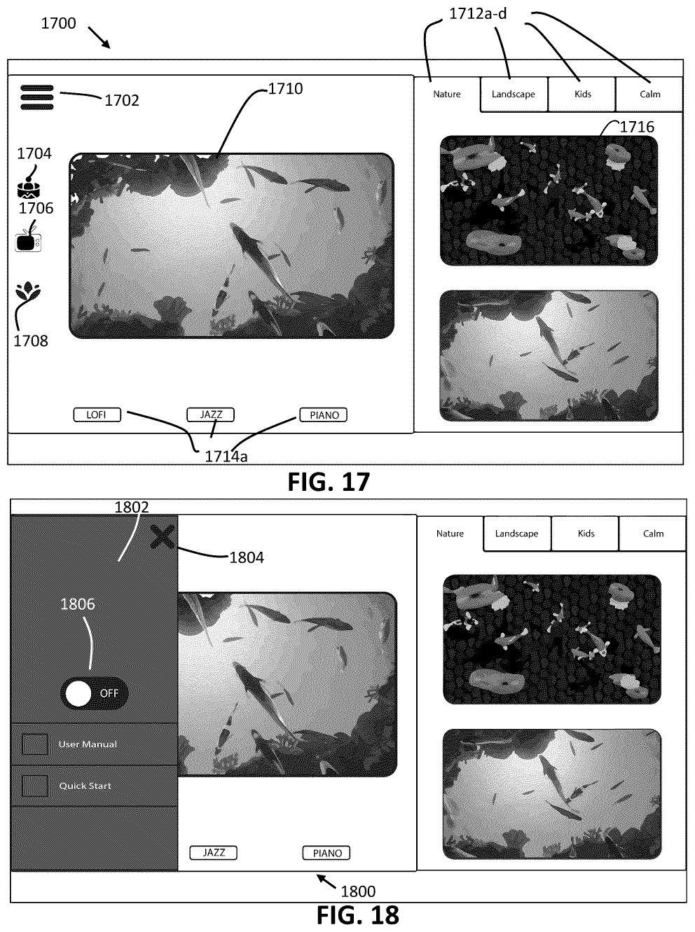

FIG. 17 illustrates a homepage 1700 allowing one to cause the projector to display several types of audio and video content. The homepage 1700 includes a menu link 1702. The homepage 1700 also includes audio genre selections 1714a-c, which, in the example of FIG. 17, includes lo-fi selection 1714a, jazz selection 1714b and plano selection 1714c. The homepage 1700 further includes within-genre selection 1716.

In some embodiments, an immersive link 1704, a cinema link 1706 and an ambiance link 1708 may also be used for selecting different sources of content, such as the cinema link 1706. The menu link 1702 opens a list of menu options, which include an on/off-link.

The immersive link 1704, the cinema link 1706 and the ambiance link 1708 each represents a different mode of operation. In some embodiments, the immersive link 1704 causes the projector 112 to project images on the bore walls and to play an accompanying audio track. Similarly, the ambiance mode 1708 causes the projector 112 to play music and illuminate at least the area occupied by the patient. In some embodiments, the nature of the illumination changes with time. In some embodiments, the illumination includes a light show that accompanies the audio track. The cinema link 1706 places the interface into a different mode of operation than the immersive link 1704. In some embodiments, during the cinema mode, the image is projected onto a screen (other than the bore walls) for viewing by the patient. By contrast, if the immersive link 1704 or the ambiance link 1708 are selected, the video content and audio content are determined by the selection. After changing to the on-state, the menu box provides a link, which when selected turns the projector 112 off.

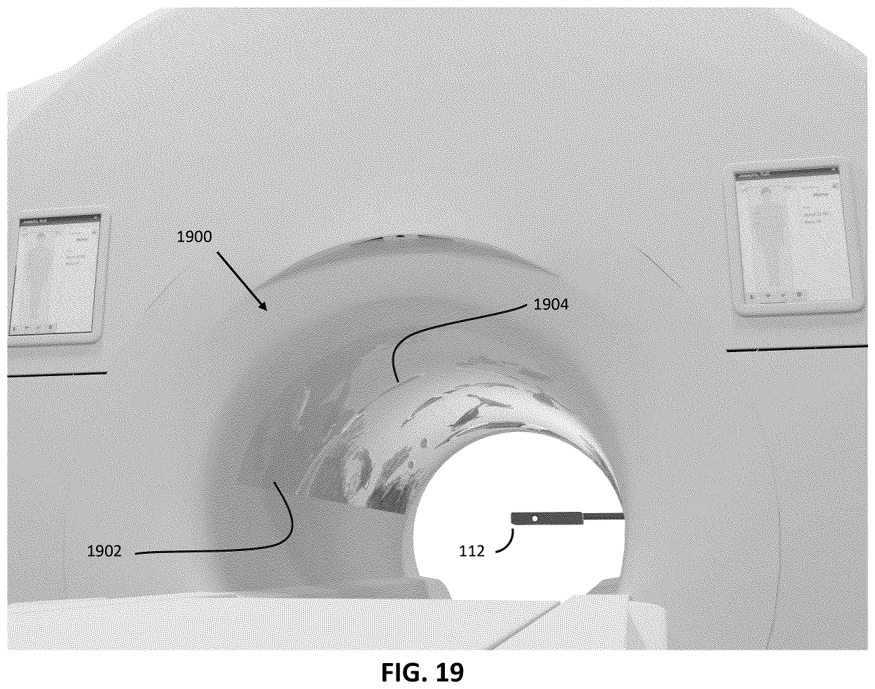

FIG. 18 illustrates a homepage 1800, which is the homepage 1700 after the menu link 1702 was selected. The homepage 1800 includes a menu box 1802, a close link 1804 and an on/off-link 1806. The menu box 1802 opens in response to selecting the menu link 1702. The on/off-link 1806, when selected, closes the menu box 1802. The on/off-link 1806 has two states. In a first of the two states, in which the projector 112 is initially off, selecting the on/off-link 1806 causes the projector 112 to turn on. In a second of the two states, in which the projector 112 is initially on, selecting the on/off-link 1806 causes the projector 112 to turn off.

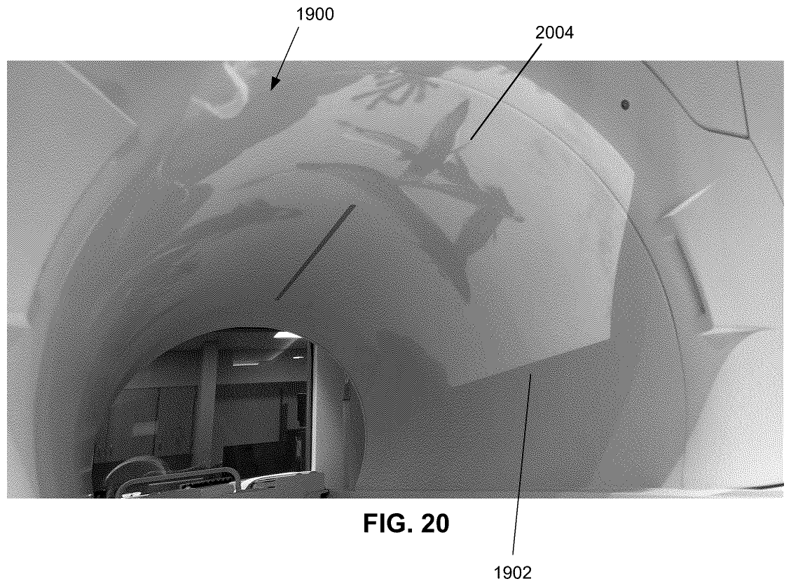

FIGS. 19 and 20 illustrate examples of a bore of an MRI system 1900, having MRI bore walls 1902, with an image 1904 (FIG. 19) and an image 2004 (FIG. 20) is projected upon the MRI bore walls 1902. In contrast, in FIG. 20, an image 2004 is projected upon the MRI bore walls 1902. Also, FIG. 19 illustrates the orientation of projector 112 with respect to the MRI bore walls 1902, whereas FIG. 20 illustrates a clearer view of the image on the MRI bore walls 1902.

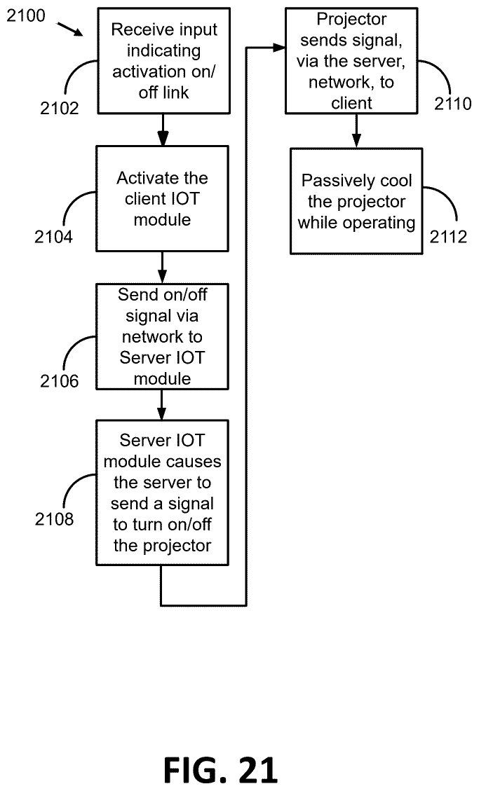

FIG. 21 illustrates a method 2100 of turning on the projector 112. Input is received at the client device 122 indicating that the on/off-link 1630 is activated (STEP 2102). In response to receiving the input, the client IOT module 1620 is activated (STEP 2104). As a result of activating the client IOT module 1620, a signal is sent to the server IOT module 1604 (STEP 2106). As a result of the server IOT module 1604 receiving the signal, a signal is sent from the server 120 to the projector 112, which turns the projector 112 on/off (STEP 2108).

The server 120 detects the state of the projector 112, and in some embodiments, detects whether the projector 112 was turned on or off. Also, the server 120 sends, via the server IOT module 1604, a signal to the client IOT module 1620, which in turn causes an indication to appear at the client device 122 indicating that the projector 112 is on/off (STEP 2110).

The projector 112 is passively cooled while the projector 112 is warmer than the ambient temperature (see the discussion of FIGS. 2-4). Although the above description of the method 2100 uses the example of sending a signal to turn on or turn off the projector 112, the same method is also applied to send other command signals from the client device 122, via the client IOT module 1620 and the server IOT module 1604 to the projector 112 (allowing the client device 122 to completely control the projector 112). See the discussion of FIGS. 1 and 16 regarding the on/off-links and the communications link between devices (STEP 2112).

The step 2112 is performed simultaneously with, or in any order with respect to, the steps 2102-2110, as needed.

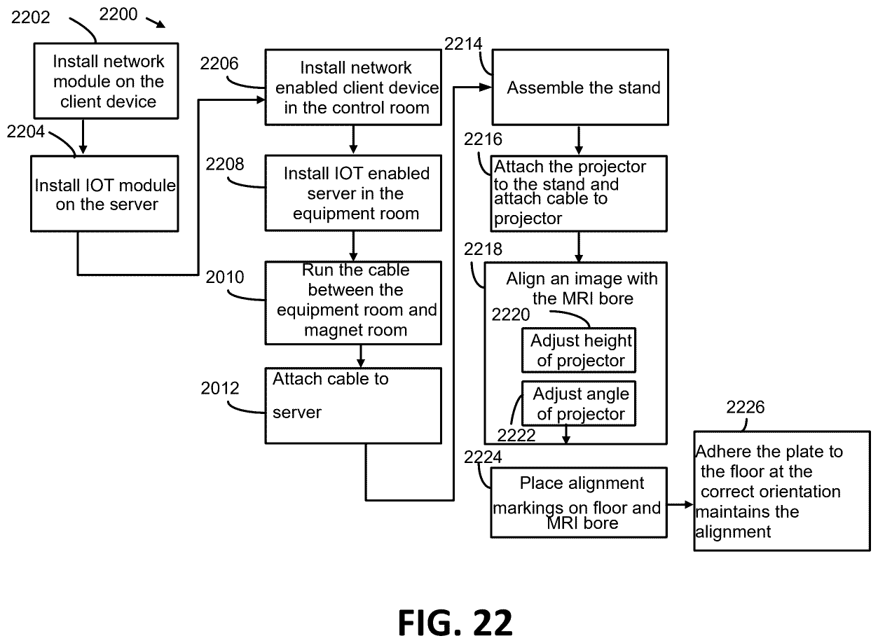

FIG. 22 illustrates a method 2200 of setting up the MRI system 100. In a step 2202, the UI module that includes the on/off-link 1630 is installed on the client device 122 (as well as other modules, see the discussion of FIG. 16) (STEP 2202). The various modules of the system of FIG. 16 are installed on the server 120 and the client device 122 (STEP 2204). The client device 122 (which in some embodiments is network enabled) is installed in the control room 106 (see the discussion of FIG. 1) (STEP 2206). The sever 120 (which in some embodiments is network enabled) is installed in the equipment room 104 (see the discussion of FIG. 1) (STEP 2208). The cable 116 is run between the magnet room 102 and the equipment room 104 (see the discussion of FIG. 1) (STEP 2210). The cable 116 is attached to the server 120 (see the discussion of FIG. 1) (STEP 2212). The stand 114 is assembled (see the discussion of FIGS. 5-7, 11 and 12) (STEP 2214). The projector 112 is attached to the stand 114 (see the discussion of FIGS. 7 and 8), and the cable 116 is clipped to (or otherwise attached to) the stand 114 (see the discussion of FIGS. 9 and 11) and electrically connected to the projector 112 (see the discussion of FIGS. 8 and 9) (STEP 2216). The steps 2202-2216 can be performed in any order with respect to one another.

The projector 112 is aligned by aligning the image projected by the projector 112 with the walls of the MRI bore (see the discussion of FIGS. 9 and 10) (STEP 2218).

In some embodiments, the step 2218 includes sub-steps 2220 and 2222. The height (and distance to the MRI bore) of the projector 112 is adjusted (see the discussion of FIGS. 7-9). In some embodiments, adjusting the height involves using a measurement tool to find an initial height of the projector and an initial distance of the projector to the vertical exterior wall of magnet housing 108. After the initial position and height of the projector 112 are found, the position and orientation of the projector 112 are further refined based on when an image from the projector aligns with the MRI bore (STEP 2220). The angle of the projector 112 is changed (see the discussion of FIGS. 9 and 10) (STEP 2222).

After the initial setup, when subsequently setting up the projector 112, the alignment of projector 112 is performed by rolling the projector 112 over the locking base 1400 engaging the push screw 1500, and if needed angling the projector until the image of the alignment markings aligns with the alignment markings 1002a and b (see the discussion of FIGS. 10, 14 and 15) (more about STEP 2218).

An image of the alignment markings is projected onto the outside of the MRI bore, and physical alignment markings are placed on the floor and the MRI bore. In some embodiments, alignment dots, such as the alignment dots 1002a and b, are placed on the magnet housing 108 covering the image of the alignment markings (see the discussion of FIG. 10), and alignment markings are placed on the floor, making the location of the plate 1400 (see the discussion of FIGS. 9, 14 and 15). After the image is aligned, the alignment markings can be placed on the floor and the MRI bore can be placed in any order with respect to one another, so long as the orientation of the projector is not disturbed (STEP 2224).

The plate 1400 is adhered to the floor, which could be performed before or after disengaging the base 502 from the plate 1400 (see the discussion of FIGS. 14 and 15) (STEP 2226). After the initial setup, the steps 2224 and 2226 need not be repeated.

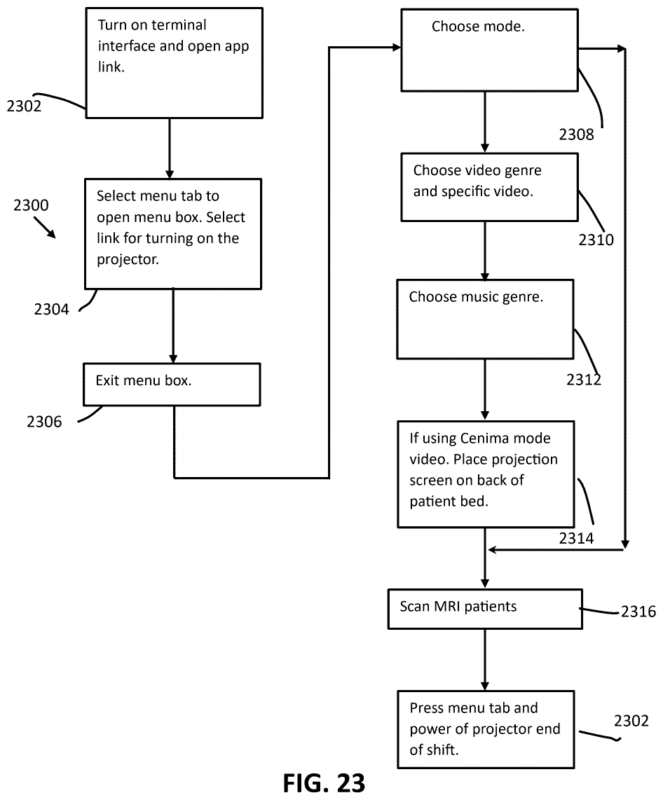

FIG. 23 illustrates a method 2300 of interacting with the interface of the homepage 1700/1800. A terminal is turned on and an app opens which serves as the interface to the projector 112 (see the discussion of FIGS. 1, 17 and 18) (STEP 2302).

The menu link 1702 is selected, and, in response, the menu box 1802 appears (see FIG. 18). Then, the on/off-link 1806 is selected, and the homepage 1700/1800 toggles to the on-state (see the discussion of the homepage 1700/1800) (STEP 2304). The menu box 1802 is closed, via the close link 1804 (see the discussion of the homepage 1800) (STEP 2306).

One of the immersive link 1704, the cinema link 1706 and the ambiance link 1708 is selected, which determines the mode of the interface of the homepage 1700/1800 (see the discussion of the homepage 1800). If the immersive link 1704 or the ambiance link 1708 is selected, the method 2300 proceeds to a step 2316 (STEP 2308). A video genre and then a specific video of that genre is selected (see the discussion of the homepage 1800) (STEP 2310).

If the full-bore video mode was selected, a music genre is chosen (STEP 2312). A projection screen is set up on a back portion of the patient bed (see the discussion of the homepage 1800) (STEP 2314). Patients are scanned by the MRI system (see the discussion of the homepage 1800) (STEP 2316).

The on/off-link 1806 is selected and the projector 112 is turned off. In some embodiments, to initiate a patient scan, the menu box 1802 is opened, the on/off-link 1806 is selected and the system toggles to the off-state. In some embodiments, the turning off of the projector is performed at the end of a shift in which several MRI scans of several patients were captured (see the discussion of the homepage 1800) (STEP 2318).

### EXAMPLE EMBODIMENTS

Embodiment 1. An MRI (Magnetic Resonance Imaging) projector system comprising:
i. a projector (112) having a heat sink (e.g., housing 200);
ii. a surface area of the heat sink (e.g., housing 200) being sufficiently large to passively cool the projector (112) while projecting images into an MRI bore of an MRI system (100) while the MRI system (100) collects magnetic resonance images; and
iii. a stand that holds the projector (112) above a bed (110a) of the MRI system (100), while the projector (112) projects images into the MRI bore.

Embodiment 2. The MRI projector system (100) of any of Embodiments 1-21, wherein the MRI system is capable of generating a magnetic field having a flux density of 3 Tesla.

Embodiment 3. The MRI projector system of any of Embodiments 2 and 3 further comprising:
a metallic housing (e.g., housing 200), which shields electronics of the projector (112) from leaking electromagnetic radiation from within the metallic housing (e.g., housing 200) to outside of the metallic housing (e.g., housing 200).

Embodiment 4. The MRI projector system of Embodiment 3, the metallic housing (e.g., housing 200) being constructed so that to escape from the housing (200), electromagnetic radiation needs to travel through a pathway that makes a turn of at least 90 degrees.

Embodiment 5. The MRI projector system of any of Embodiments 3 and 4, the metallic housing (e.g., housing 200) having
a removable lid (e.g., lid 206), the removable lid (lid 206) resting on a ledge (302) surrounding an interior of the metallic housing (e.g., housing 200); and
the ledge (302) being oriented at a 90-degree angle with respect to walls of the interior of the metallic housing (e.g., housing 200) so that while the removable lid (lid 206) is resting on the ledge, electromagnetic radiation needs to travel through a 90-degree turn to exit the metallic housing (200).

Embodiment 6. The MRI projector system of any of Embodiments 1-21,
the projector (112) including a controller that controls the projector (112);
the controller being located within a housing (200), the projector (112) being housed in the housing (200), the heat sink including the housing (200);
the MRI projector system further comprising:
a server (120) that stores software that controls the controller of the projector (112).

Embodiment 7. The MRI projector system of any of Embodiments 6-11, the server (120) being located in a room (102) that is shielded from a magnetic field of the MRI system (100).

Embodiment 8. The MRI projector system of any of Embodiments 6-11, the server (120) being IOT (Internet of Things) enabled.

Embodiment 9. The MRI projector system of any of Embodiments 6-11, further comprising a client device (122) storing a UI (User Interface) for the software on the server (120) that controls a controller of the projector (112).

Embodiment 10. The MRI projector system (100) of any of Embodiments 6-11, the MRI projector system (100) further comprising a client device (122) having a UI (User Interface) the UI including a page (e.g., the homepage 1700 or 1800) having an on/off-link (1806), which when activated turns the projector (112) on and off.

Embodiment 11. The MRI projector system of any of Embodiments 6-11, further comprising:
a shielded cable (e.g., cable 116) that communicatively connects the projector (112) and the server (120).

Embodiment 12. The MRI projector system of any of Embodiments 1-23, further comprising:
a power supply located on a PCB (Printed Circuit Board), within the projector (112) housing (e.g., housing 200).

Embodiment 12. The MRI projector of any of Embodiments 1-12, wherein the image contains aesthetic content.

Embodiment 13. The MRI projector system of Embodiments 1-14 further comprising a server (120) including:
i. a processor system (1612);
ii. a memory system (1614); and
iii. a projector driver (1610);
the memory system (1614) storing:
a) a library of video content (1616), including multiple versions of at least one video, each version generating an image of a different size, each size being appropriate for a different MRI bore size; and
b) one or more machine instructions, which, when implemented, selects one of the multiple versions based on input indicative of a MRI bore size.

Embodiment 14. The MRI projector system of Embodiments 1-14 further comprising a user device (122) including:
i. a processor system (1626);
ii. a memory system (1628); and
iii. a UI (User Interface) module, which when activated generates input tools, the input tools receive input, which when sent to a server (120), causes the server to control a projector (112) in a magnet room (102) of an MRI (Magnetic Resonance Imaging) system (100);
the input tools including a tool for turning the projector on and off and changing image size within and around the MRI bore.

Embodiment 15. A server (120) comprising:
i. a processor system (1612);
ii. a memory system (1614); and
iii. a projector driver (1610);
the memory system (1614) storing:
   a) a library of video content (1616), including multiple versions of at least one video, each version generating an image of a different size, each size being appropriate for a different MRI bore size; and
   b) one or more machine instructions, which, when implemented, selects one of the multiple versions based on input indicative of a MRI bore size.

Embodiment 16. The server (120) of any of the Embodiments 13 and 15-22, the memory (1614) storing videos for the projector (112) to play.

Embodiment 17. The server (120) of any of the Embodiments 13 and 15-22, the memory (1614) storing one or more machine instructions, which when implemented, cause the processor system (1612) to control functions of the projector (112).

Embodiment 18. The server (120) of any of the Embodiments 13 and 15-22, the memory (1614) storing computer instructions, which when implemented, control turning the projector (112) on and turning the projector (112) off.

Embodiment 19. The server (120) of any of the Embodiments 13 and 15-22, the memory (1614) storing computer instructions, which when implemented, controls turning the projector (112) on and turning the projector (112) off.

Embodiment 20. The server (120) of any of the Embodiments 13 and 15-22, an IOT (Internet Of Things) module (1604) enabling the projector (112) to be controlled from a remote device, via the server (120).

Embodiment 21. The server (120) of any of the Embodiments 13 and 15-22, the server (120) being installed in a room electromagnetically isolated from the magnet room (108).

Embodiment 22. A user device (122) comprising:
i. a processor system (1626);
ii. a memory system (1628); and
iii. a UI (User Interface) module, which when activated generates input tools, the input tools receive input, which when sent to a server (120), cause the server (120) to control a projector (112) in a magnet room (102) of an MRI (Magnetic Resonance Imaging) system; and
the input tools including a tool for turning the projector on and off and changing image size within and around the MRI bore

Although the disclosed method and apparatus are described above in terms of various examples of embodiments and implementations, it should be understood that the particular features, aspects and functionality described in one or more of the individual embodiments are not limited in their applicability to the particular embodiment with which they are described. Thus, the breadth and scope of the claimed invention should not be limited by any of the examples provided in describing the above disclosed embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide examples of instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosed method and apparatus may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described with the aid of block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. An MRI (Magnetic Resonance Imaging) projector system comprising:
i. a projector having a heat sink;
ii. a surface area of the heat sink being sufficiently large to passively cool the projector while projecting images into an MRI bore of an MRI system while the MRI system collects magnetic resonance images; and
iii. a stand that holds the projector above a bed of the MRI system, while the projector projects optical images into the MRI bore.

2. The MRI projector system of claim 1 wherein the MRI system is capable of generating a magnetic field having a flux density up to 3 Tesla.

3. The MRI projector system of claim 1 further comprising:
a metallic housing, which shields electronics of the projector from leaking electromagnetic radiation outside of the metallic housing.

4. The MRI projector system of claim 3, the metallic housing having
a removable lid, the removable lid resting on a ledge surrounding an interior of the metallic housing; and
the ledge being oriented at an angle of 90 degrees with respect to walls of the interior of the metallic housing so that while the removable lid is resting on the ledge, electromagnetic radiation needs to travel through a 90-degree turn to exit that housing.

5. The MRI projector system of claim 1, the projector including a controller that controls the projector; and the controller being located within a housing, the projector being housed in the housing, the heat sink including the housing.

6. The MRI projector system of claim 1, the MRI projector system further comprising:
a server that includes a module that controls the projector.

7. The MRI projector system of claim 6, the server being located in a room that is RF shielded from the MRI system.

8. The MRI projector system of claim 6, the server having an IOT (Internet of Things) module.

9. The MRI projector system of claim 6, further comprising a client device storing a UI (User Interface) for a control module on the server that controls the projector.

10. The MRI projector system of claim 6, the MRI projector system further comprising a client device having a UI (User Interface) the UI including a page having an on/off-link, which when activated turns the projector on and off.

11. The MRI projector system of claim 6, further comprising:
a shielded cable that communicatively connects the projector and the server.

12. A server comprising:
i. a processor system;
ii. a projector driver; and
iii. a memory system;
the memory system storing:
iv. a library of video content, including multiple versions of at least one video, each version generating an image of a different size, each size being appropriate for a different MRI bore size; and
v. one or more machine instructions, which, when implemented, selects one of the multiple versions based on input indicative of the MRI bore size.

13. The server of claim 12, the memory storing videos for the projector to play.

14. The server of claim 12, the memory system storing one or more machine instructions, which when implemented, cause the processor system to control functions of the projector.

15. The server of claim 12, the memory storing computer instructions, which when implemented, controls turning the projector on and turning the projector off.

16. The server of claim 12, an IOT (Internet Of Things) module enabling a projector to be controlled from a remote device, via the server.

17. The server of claim 12, the server being installed in a room electromagnetically isolated from the magnet room.

18. A user device comprising:
i. a processor system;
ii. a memory system; and
iii. a UI (User Interface) module, which when activated generates input tools, the input tools receive input, which when sent to a server, causes the server to control a projector in a magnet room of an MRI (Magnetic Resonance Imaging) system; and
the input tools including a tool for turning the projector on and off.

20. The user device of claim 19 being installed in a control room of the MRI system.
